(19) United States
(12) Patent Application Publication
(10) Pub. No.: US 2016/0379762 A1
(43) Pub. Date: Dec. 29, 2016

(54) PHOTOELECTRIC CONVERSION ELEMENT

(71) Applicant: Kabushiki Kaisha Toshiba, Minato-ku (JP)

(72) Inventor: Takeshi GOTANDA, Yokohama (JP)

(73) Assignee: Kabushiki Kaisha Toshiba, Minato-ku (JP)

(21) Appl. No.: 15/263,575

(22) Filed: Sep. 13, 2016

Related U.S. Application Data
(63) Continuation of application No. PCT/JP2015/066641, filed on Jun. 9, 2015.

(30) Foreign Application Priority Data
Sep. 22, 2014 (JP) 2014-192261

(51) Int. Cl. H01G 9/20; H01L 51/42; H01L 51/44

(52) U.S. Cl. CPC H01G 9/2018; H01L 51/442; H01L 51/4253; H01L 51/0037

(57) ABSTRACT

According to one embodiment, a photoelectric conversion element includes a first electrode, a second electrode, a photoelectric conversion layer, a first buffer layer, a second buffer layer, and a third buffer layer. The second electrode is separated from the first electrode. The photoelectric conversion layer is provided between the first electrode and the second electrode. The first buffer layer is provided between the first electrode and the photoelectric conversion layer. The second buffer layer is provided between the second electrode and the photoelectric conversion layer. The third buffer layer is provided at an end portion of the first electrode.

### CROSS-REFERENCE TO RELATED APPLICATIONS

This is a continuation application of International Application PCT/JP2015/066641, filed on Jun. 9, 2015. This application also claims priority to Japanese Application No. 2014-192261, filed on Sep. 22, 2014. The entire contents of each are incorporated herein by reference.

### FIELD

Embodiments described herein relate generally to a photoelectric conversion element.

### BACKGROUND

Solar cells, sensors, and the like using an organic photoelectric conversion material or a photoelectric conversion material containing an organic compound and an inorganic compound have been studied and developed. If solar cells and the like can be produced by applying or printing a photoelectric conversion material, there is a possibility that a device can be fabricated at relatively low cost.

In the case where a photoelectric conversion layer is formed by application, when an ink containing a photoelectric conversion material is applied onto an electrode, a thickness of the photoelectric conversion layer formed in an end portion of a foundation electrode is thinner than a thickness of the photoelectric conversion layer in a portion other than the end portion due to the flowing of the ink. The end portion of the electrode is a portion on which an electric field is concentrated. Due to this, when the thickness of the photoelectric conversion layer is relatively thin, a shunt resistance decreases so that the device characteristics may sometimes be deteriorated. It is desired to suppress the decrease in the shunt resistance in a photoelectric conversion element.

### BRIEF DESCRIPTION OF THE DRAWINGS

FIG. 1A to FIG. 1D are schematic views showing a photoelectric conversion element according to an embodiment;

FIG. 2A and FIG. 2B are a table and a graph showing first example of the photoelectric conversion element according to the embodiment;

FIG. 3 shows an EMS (Emission Microscopy) image of the photoelectric conversion element according to first comparative example;

FIG. 4A to FIG. 4C are schematic views showing the photoelectric conversion element according to first comparative example;

FIG. 5 is a graph showing second example of the photoelectric conversion element according to the embodiment;

FIG. 6A and FIG. 6B are a table and a graph showing third example of the photoelectric conversion element according to the embodiment; and

FIG. 7A and FIG. 7B are a table and a graph showing third example of the photoelectric conversion element according to the embodiment.

### DETAILED DESCRIPTION

According to one embodiment, a photoelectric conversion element includes a first electrode, a second electrode, a photoelectric conversion layer, a first buffer layer, a second buffer layer, and a third buffer layer. The second electrode is separated from the first electrode. The photoelectric conversion layer is provided between the first electrode and the second electrode. The first buffer layer is provided between the first electrode and the photoelectric conversion layer. The second buffer layer is provided between the second electrode and the photoelectric conversion layer. The third buffer layer is provided at an end portion of the first electrode.

Various embodiments will be described hereinafter with reference to the accompanying drawings.

The drawings are schematic and conceptual; and the relationships between the thickness and width of portions, the proportions of sizes among portions, etc., are not necessarily the same as the actual values thereof. Further, the dimensions and proportions may be illustrated differently among drawings, even for identical portions.

In the specification and drawings, components similar to those described or illustrated in a drawing thereinabove are marked with like reference numerals, and a detailed description is omitted as appropriate.

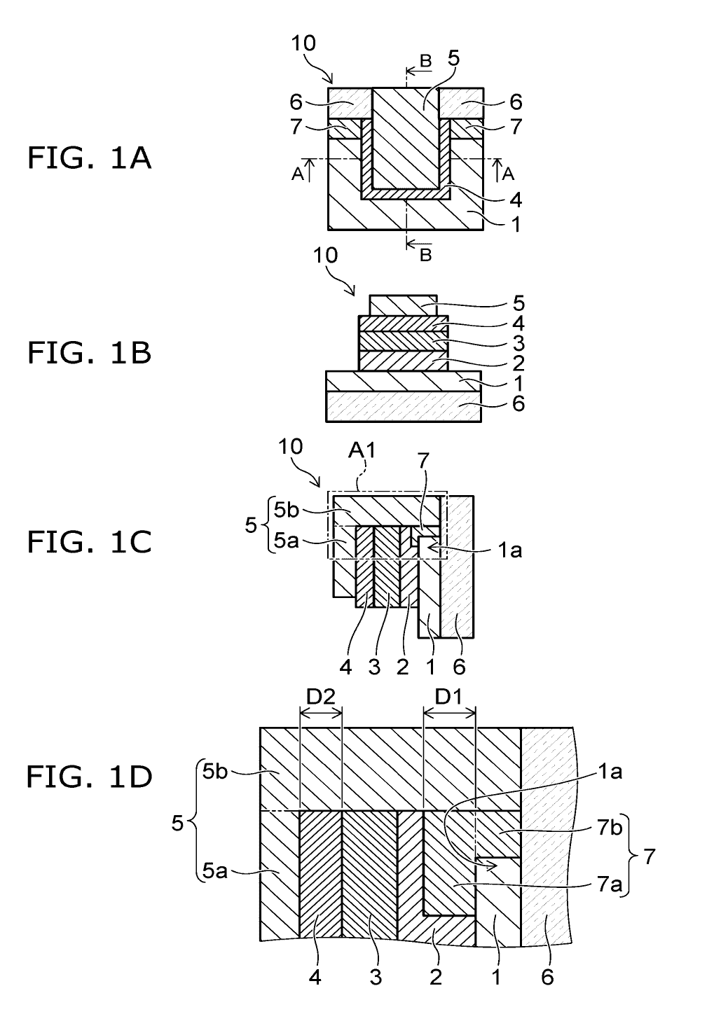

FIG. 1 is a schematic view showing a photoelectric conversion element according to an embodiment.

FIG. 1A is a schematic plan view showing the photoelectric conversion element of the embodiment. FIG. 1B is a schematic cross sectional view taken at plane A-A shown in FIG. 1A. FIG. 1C is a schematic cross sectional view taken at plane B-B shown in FIG. 1A. FIG. 1D is a schematic enlarged view magnifying the region A1 shown in FIG. 1C.

A photoelectric conversion element 10 according to the embodiment includes a first electrode 1, a first buffer layer 2, a photoelectric conversion layer 3, a second buffer layer 4, a second electrode 5, a substrate 6, and a third buffer layer 7. The photoelectric conversion element 10 according to the embodiment may be, for example, a solar cell, or a sensor. The photoelectric conversion layer 3 is formed by coating, and contains at least one of an organic semiconductor material, or a material having a perovskite structure.

As shown in FIG. 1B, the second electrode 5 is provided by being spaced from the first electrode 1. The first electrode 1 is provided between the substrate 6 and the second electrode 5. The first buffer layer 2 is provided between the first electrode 1 and the second electrode 5. The photoelectric conversion layer 3 is provided between the first buffer layer 2 and the second electrode 5. The second buffer layer 4 is provided between the photoelectric conversion layer 3 and the second electrode 5.

As shown in FIGS. 1A and 1C, the third buffer layer 7 is provided at end portions 1a of the first electrode 1.

Specifically, as shown in FIG. 1D, the second electrode 5 has a first portion 5a and a second portion 5b. The first portion 5a is provided on the second buffer layer 4. The second portion 5b extends from the first portion 5a to the first electrode 1. The third buffer layer has a first buffer portion 7a, and a second buffer portion 7b. The first electrode 1, the first buffer layer 2, the photoelectric conversion layer 3, and the second buffer layer 4 are provided between the substrate 6, and the first portion 5a of the second electrode 5. The first buffer portion 7a of the third buffer layer 7 is provided between the first electrode 1, and the first portion 5a of the second electrode 5. The second buffer portion 7b of the third buffer layer 7 is provided between the first electrode 1, and the second portion 5b of the second electrode 5.

One of the first electrode 1 and the second electrode 5 represents an anode. The other of the first electrode 1 and the second electrode 5 is the cathode. Electricity is extracted from the first electrode 1 and the second electrode 5. The photoelectric conversion layer 3 is excited by light that is incident through the substrate 6, the first electrode 1, and the first buffer layer 2, or by light that is incident through the second electrode 5 and the second buffer layer 4. Electrons occur at one of the first electrode 1 and the second electrode 5. Holes occur at the other of the first electrode 1 and the second electrode 5.

The following describes the constituent members of the photoelectric conversion element 10 according to the embodiment.

### (Substrate 6)

The substrate 6 supports the other constituent members (constituent members other than the substrate 6). The substrate 6 can form an electrode. Favorably, the substrate 6 is one that does not alter under heat or organic solvent. Examples of the material of the substrate 6 include inorganic materials, plastics, polymer films, and metal substrates. Examples of the inorganic materials include alkali-free glass, and fused quartz. Examples of the plastics and polymer films include polyethylene, polyethylene terephthalate (PET), polyethylene naphthalate (PEN), polyimide, polyamide, polyamideimide, liquid crystal polymers, and cycloolefin polymers. Examples of the material of the metal substrates include stainless steel (SUS), and silicon.

A transparent substrate is used when the substrate 6 is disposed on the light incident side. Specifically, when the substrate 6 is disposed on the light incident side, materials having light transmissivity are used for the substrate 6. When the electrode opposite the substrate 6 (the second electrode 5 in the embodiment) is transparent or semi-transparent, a nontransparent substrate may be used as the substrate 6. The thickness of the substrate 6 is not particularly limited, provided that the substrate 6 is sufficiently strong to support the other constituent members.

When the substrate 6 is disposed on the light incident side, it is possible to efficiently take in light, and improve the energy conversion efficiency of the cell with the installation of, for example, a reflection preventing film of a moth-eye structure on the light-incident surface. The moth-eye structure has orderly arrayed projections of approximately 100 nanometers (nm) on its surface. The projection structure of the moth-eye structure continuously varies the refractive index in thickness direction. Surfaces with discontinuously changing refractive indices can thus be reduced by interposing a nonreflecting film. This reduces reflection of light, and improves the cell efficiency.

### (First Electrode 1 and Second Electrode 5)

In descriptions made in conjunction with first electrode 1 and second electrode 5, simple reference to “electrode” is meant to indicate at least one of the first electrode 1 or the second electrode 5.

The first electrode 1 and the second electrode 5 are not particularly limited, as long as these are conductive. A transparent or semi-transparent material having conductivity is used as the material of the electrode on the light passing side (for example, the first electrode 1). The first electrode 1 and the second electrode 5 are formed by using methods such as a vacuum vapor deposition method, a sputtering method, an ion plating method, a plating method, and a coating method. Examples of the transparent or semi-transparent electrode material include conductive metal oxides, and semi-transparent metals. Specifically, materials such as conductive glass, gold, platinum, silver, and copper are used as materials of the transparent or semi-transparent electrode. Examples of the conductive glass include indium oxide, zinc oxide, tin oxide, and complexes of these, including indium tin oxide (ITO), fluorine doped tin oxide (FTO), and indium zinc oxide. For example, the electrode is fabricated as a film (such as NESA) or a layer containing conductive glass. The preferred electrode material is, for example, ITO or FTO. The electrode material may be, for example, organic conductive polymer polyaniline or derivatives thereof, or polythiophene or derivatives thereof.

When the electrode material is ITO, the electrode thickness is favorably not less than 30 nm and not more than 300 nm. The conductivity decreases, and the resistance increases when the electrode is thinner than 30 nm. Low conductivity becomes a factor that lowers photoelectric conversion efficiency. The flexibility of ITO suffers when the electrode is thicker than 300 nm. Poor ITO flexibility may cause cracking in ITO under applied stress.

The electrode should have as small a sheet resistance as possible, favorably not more than 10Ω/□. The electrode may be a monolayer, or may have a structure with stacked layers containing materials having different work functions.

When the electrode is formed in contact with the electron transport layer, it is favorable to use a low-work-function material as the electrode material. Examples of such low-work-function materials include alkali metals, and alkali earth metals. Specific examples of low-work-function materials include Li, In, Al, Ca, Mg, Sm, Tb, Yb, Zr, Na, K, Rb, Cs, Ba, and alloys thereof. The electrode may be a monolayer, or may have a structure with stacked layers containing materials having different work functions. The electrode material may be an alloy of at least one of the low-work-function materials exemplified above, and at least one of gold, silver, platinum, copper, manganese, titanium, cobalt, nickel, tungsten, or tin. Examples of such alloys include lithium-aluminum alloys, lithium-magnesium alloys, lithium-indium alloys, magnesium-silver alloys, calcium-indium alloys, magnesium-aluminum alloys, indium-silver alloys, and calcium-aluminum alloys.

When the electrode is formed in contact with the electron transport layer, the electrode thickness is favorably not less than 1 nm and not more than 500 nm. Preferably, the electrode thickness is not less than 10 nm and not more than 300 nm. When the electrode is thinner than 1 nm, the resistance increases, and it may not be possible to sufficiently transmit the generated charge to an external circuit as compared to when the electrode thickness is not less than 1 nm. It takes a relatively longer time to form electrode when the electrode is thicker than 500 nm. This raises the material temperature, and may result in poor performance as it damages the other materials. Further, because of the need to use large quantities of material, there is a need to use an electrode forming apparatus (for example, a deposition device) for extended time periods. This raises costs.

When the electrode is formed in contact with the hole transport layer, it is favorable to use a high-work-function material as the electrode material. Examples of such high-work-function materials include Au, Ag, Cu, and alloys thereof. The electrode may be a monolayer, or may have a structure with stacked layers containing materials having different work functions.

When the electrode is formed in contact with the hole transport layer, the electrode thickness is favorably not less than 1 nm and not more than 500 nm. Preferably, the electrode thickness is not less than 10 nm and not more than 300 nm. When the electrode is thinner than 1 nm, the resistance increases, and it may not be possible to sufficiently transmit the generated charge to an external circuit as compared to when the electrode thickness is not less than 1 nm. It takes a relatively longer time to form electrode when the electrode is thicker than 500 nm. This raises the material temperature, and may result in poor performance as it damages the other materials. Further, because of the need to use large quantities of material, there is a need to use an electrode forming apparatus (for example, a deposition device) for extended time periods. This raises costs.

### First Buffer Layer 2, Second Buffer Layer 4, and Third Buffer Layer 7

One of the first buffer layer 2 and the second buffer layer 4 is provided between the photoelectric conversion layer 3 and the first electrode 1. The other of the first buffer layer 2 and the second buffer layer 4 is provided between the photoelectric conversion layer 3 and the second electrode 5. In the example represented in FIGS. 1A to 1D, the first buffer layer 2 is provided between the photoelectric conversion layer 3 and the first electrode 1. In the example represented in FIGS. 1A to 1D, the second buffer layer 4 is provided between the photoelectric conversion layer 3 and the second electrode 5.

One of the first buffer layer 2 and the second buffer layer 4 is a hole transport layer. The other of the first buffer layer 2 and the second buffer layer 4 is an electron transport layer. The preferred materials of the second buffer layer 4 and the third buffer layer 7 are halogen compounds or metal oxides. Favorably, the material of the second buffer layer 4, and the material of the third buffer layer 7 are the same. As shown in FIG. 1D, the thickness D1 of the first buffer portion 7a of the third buffer layer 7 is favorably thicker than the thickness D2 of the second buffer layer 4.

Examples of the halogen compounds include LIE, LiCl, LiBr, LiI, NaF, NaCl, NaBr, NaI, KF, KCl, KBr, KI, and CsF. Preferred examples of the halogen compounds include LiF.

Examples of the metal oxides include titanium oxide, molybdenum oxide, vanadium oxide, zinc oxide, nickel oxide, lithium oxide, calcium oxide, cesium oxide, and aluminum oxide.

The hole transport layer may use, for example, polythiophene-based polymers such as PEDOT:PSS (poly(3,4-ethylenedioxythiophene)-poly(styrenesulfonate)), and organic conductive polymers such as polyaniline, and polypyrrole. Typical examples of the polythiophene-based polymers include the Clevios PH500, Clevios PH, Clevios PV P AI 4083, and Clevios HIL1,1 available from Stark. Examples of the inorganic materials include molybdenum oxide.

When Clevios PH500 is used as the hole transport layer material, the thickness of the hole transport layer is favorably not less than 20 nm and not more than 100 nm. When the hole transport layer is thinner than 20 nm, shorting occurs as the effect to prevent the shorting of the lower electrode (the first electrode 1 in the embodiment) becomes weaker. When the hole transport layer is thicker than 100 nm, the resistance increases, and the generated current is restricted as compared to when the hole transport layer thickness is not more than 100 nm. This results in poor light conversion efficiency. The method for forming the hole transport layer is not particularly limited, as long as a thin film can be formed. For example, a hole transport layer material may be coated using a method such as spin coating. After the hole transport layer material is coated to a desired thickness, the material is heated and dried with, for example, a hot plate. Favorably, the coated hole transport layer material is heated and dried at not less than 140° C. and not more than 200° C. for approximately at least several minutes to not more than 10 minutes. Desirably, the coating solution is filtered beforehand with a filter.

The electron transport layer functions to efficiently transport electrons. Examples of the electron transport layer material include metal oxides. Examples of the metal oxides include an amorphous titanium oxide obtained after hydrolysis of titanium alkoxide by, for example, a sol-gel method.

The method for forming the electron transport layer is not particularly limited, as long as a thin film can be formed. Examples of the electron transport layer forming method include spin coating. When titanium oxide is used as the electron transport layer material, the thickness of the electron transport layer is desirably not less than 5 nm and not more than 20 nm. The hole blocking effect becomes weaker when the electron transport layer is thinner than 5 nm. In this case, the generated excitons become deactivated before dissociating into electrons and holes, and the current cannot be efficiently extracted. When the electron transport layer is thicker than 20 nm, the resistance of the electron transport layer increases, and the generated current is restricted as compared to when the electron transport layer thickness is not more than 20 nm. This results in poor light conversion efficiency. Desirably, the coating solution is filtered beforehand with a filter.

The electron transport layer material is heated and dried with, for example, a hot plate after being coated to a specified thickness. The coated electron transport layer material is heated and dried at not less than 50° C. and not more than 100° C. for approximately at least several minutes to not more than 10 minutes while promoting hydrolysis in air. Examples of the inorganic material include metal calcium.

### (Photoelectric Conversion Layer 3)

The photoelectric conversion layer 3 may use a heterojunction or a bulk heterojunction composed of organic semiconductors. The bulk heterojunction takes a microlayer separation structure as the p-type semiconductor and the n-type semiconductor mix in the photoelectric conversion layer 3. This is typically called bulk heterojunction. The mixed p-type semiconductor and n-type semiconductor form a p-n junction of a nano-order size in the photoelectric conversion layer 3, and produce current by taking advantage of the photocharge separation that occurs at the junction plane. The p-type semiconductor contains a material having an electron donating property. On the other hand, the n-type semiconductor contains a material having an electron-accepting property. In the embodiment, at least one of the p-type semiconductor or the n-type semiconductor may be an organic semiconductor.

Examples of the p-type organic semiconductor include polythiophene and derivatives thereof, polypyrrole and derivatives thereof, pyrazoline derivatives, arylamine derivatives, stilbene derivatives, triphenyldiamine derivatives, oligothiophene and derivatives thereof, polyvinylcarbazole and derivatives thereof, polysilane and derivatives thereof, polysiloxane derivatives having an aromatic amine on the side chain or the main chain, polyaniline and derivatives thereof, phthalocyanine derivatives, porphyrin and derivatives thereof, polyphenylenevinylene and derivatives thereof, and polythienylenevinylene and derivatives thereof. These may be used in combination. It is also possible to use copolymers of these. Examples of such copolymers include thiophene-fluorene copolymers, and phenylene ethynylene-phenylenevinylene copolymers.

Preferred as the p-type organic semiconductor are polythiophene and derivatives thereof—conductive polymers having it conjugation. Polythiophene and derivatives thereof can provide relatively desirable tacticity. Polythiophene and derivatives thereof have relatively high solubility for solvent. Polythiophene and derivatives thereof are not particularly limited, as long as these are compounds having a thiophene backbone. Specific examples of polythiophene and derivatives thereof include polyalkylthiophene; poly3-phenylthiophene, polyarylthiophene; poly3-butylisothionaphthene, polyalkylisothionaphthene; and polyethylenedioxythiophene. Examples of polyalkylthiophene; and poly3-phenylthiophene include poly3-methylthiophene, poly3-butylthiophene, poly3-hexylthiophene, poly3-octylthiophene, poly3-decylthiophene, and poly3-dodecylthiophene. Examples of polyarylthiophene; and poly3-butylisothionaphthene include poly3-(p-alkylphenylthiophene). Examples of polyalkylisothionaphthene; and polyethylenedioxythiophene include poly3-hexylisothionaphthene, poly3-octylisothionaphthene, and poly3-decylisothionaphthene.

For example, derivatives of a copolymer containing carbazole, benzothiadiazole, and thiophene, specifically PCDTBT (poly[N-9″-hepta-decanyl 2,7-carbazole-alt 5,5-(4′,7′-di-2-thienyl-2′,1′,3′-benzothiadiazole)]), are known as compounds that can achieve relatively desirable photoelectric conversion efficiency.

Such conductive polymers can be formed as a film or a layer by being dissolved in a solvent and coating the solution. This enables manufacture of large-area organic thin-film solar cells at low cost with inexpensive equipment using a method such as printing.

Preferred as the n-type organic semiconductor are fullerene and derivatives thereof. The fullerene derivatives used are not particularly limited, provided that these are derivatives having a fullerene backbone. Specific examples include derivatives configured to include, for example, a C₆₀, C₇₀, C₇₆, C₇₈, or C₈₄ backbone. The fullerene derivatives may be one in which carbon atoms in the fullerene backbone are modified with any functional groups, and these functional groups may be bound to each other to form a ring. The fullerene derivatives include fullerene binding polymers. Preferred is a fullerene derivative having a functional group with high affinity for the solvent, and having high solubility for the solvent.

Examples of the functional groups in the fullerene derivatives include a hydrogen atom; a hydroxyl group; a fluorine atom, a halogen atom; a methyl group, an alkyl group; an alkenyl group; a cyano group; a methoxy group, an alkoxy group; a phenyl group, an aromatic hydrocarbon group, a thienyl group, and an aromatic heterocyclic group. Examples of the halogen atom include a chlorine atom. Examples of the alkyl group include an ethyl group. Examples of the alkenyl group include a vinyl group. Examples of the alkoxy group include an ethoxy group. Examples of the aromatic hydrocarbon group include a naphthyl group. Examples of the aromatic heterocyclic group include a pyridyl group. Specific examples include hydrogenated fullerenes such as C₆₀H₃₆ and C₇₀H₃₆, oxide fullerenes such as C₆₀ and C₇₀, and fullerene metal complexes.

Preferred as the fullerene derivatives are 60 PCBM ([6,6]-phenyl C₆₁ methyl butyrate ester), and 70 PCBM ([6,6]-phenyl C₇₁ methyl butyrate ester).

When an unmodified fullerene is used as the n-type organic semiconductor, it is favorable to use C₇₀. Fullerene C₇₀ has relatively high photo carrier generation efficiency. It is favorable to use fullerene C₇₀ for organic thin-film solar cells.

In the photoelectric conversion layer 3, a mixture ratio of the n-type organic semiconductor and the p-type organic semiconductor is preferably about 1:1 as a ratio of n-type organic semiconductor to p-type organic semiconductor when the p-type semiconductor is of P3AT. The mixture ratio of the n-type organic semiconductor and the p-type organic semiconductor is preferably about 4:1 as a ratio of n-type organic semiconductor to p-type organic semiconductor when the p-type semiconductor is of PCDTBT.

In order to coat the organic semiconductor, the organic semiconductor needs to be dissolved in a solvent. Examples of the solvent used for this purpose include unsaturated hydrocarbon-based solvents, halogenated aromatic hydrocarbon-based solvents, halogenated saturated hydrocarbon-based solvents, and ethers. Examples of the unsaturated hydrocarbon-based solvents include toluene, xylene, tetralin, decalin, mesitylene, n-butyl benzene, sec-butyl benzene, and tert-butyl benzene. Examples of the halogenated aromatic hydrocarbon-based solvents include chlorobenzene, dichlorobenzene, and trichlorobenzene. Examples of the halogenated saturated hydrocarbon-based solvents include carbon tetrachloride, chloroform, dichloromethane, dichloroethane, chlorobutane, bromobutane, chloropentane, chlorohexane, bromohexane, and chlorocyclohexane. Examples of the ethers include tetrahydrofuran, and tetrahydropyran. Preferred are halogen-based aromatic solvents. These solvents may be used alone or as a mixture.

Examples of the method for coating the solution to form a film or a layer include spin coating, dip coating, casting, bar coating, roll coating, wire bar coating, spraying, screen printing, gravure printing, flexography, offset printing, gravure-offset printing, dispenser coating, nozzle coating, capillary coating, and an inkjet method. These coating methods may be used either alone or in combination.

The photoelectric conversion layer 3 may use perovskite. Perovskite may be represented by ABX₃ composed of ion A, ion B, and ion X. When ion B is smaller than ion A, ABX₃ may have a perovskite structure. A perovskite structure has a cubic unit lattice. In a perovskite structure, ion A is disposed at each apex of the cubical crystals, and ion B is disposed at the body center, around which is ion X disposed at each face center of the cubical crystals. The orientation of a BX₆ octahedron readily strains by the interaction with ion A. A BX₆ octahedron undergoes a Mott transition as the symmetry is reduced. In a BX₆ octahedron, the valence electrons localized at ion M are able to spread as a band. Ion A is favorably CH₃NH₃. Ion B is favorably at least one of Pb or Sn. Ion X is favorably at least one of CI, Br, or I. The materials of the ion A, ion B, and ion X may constitute these ions either alone or as a mixture.

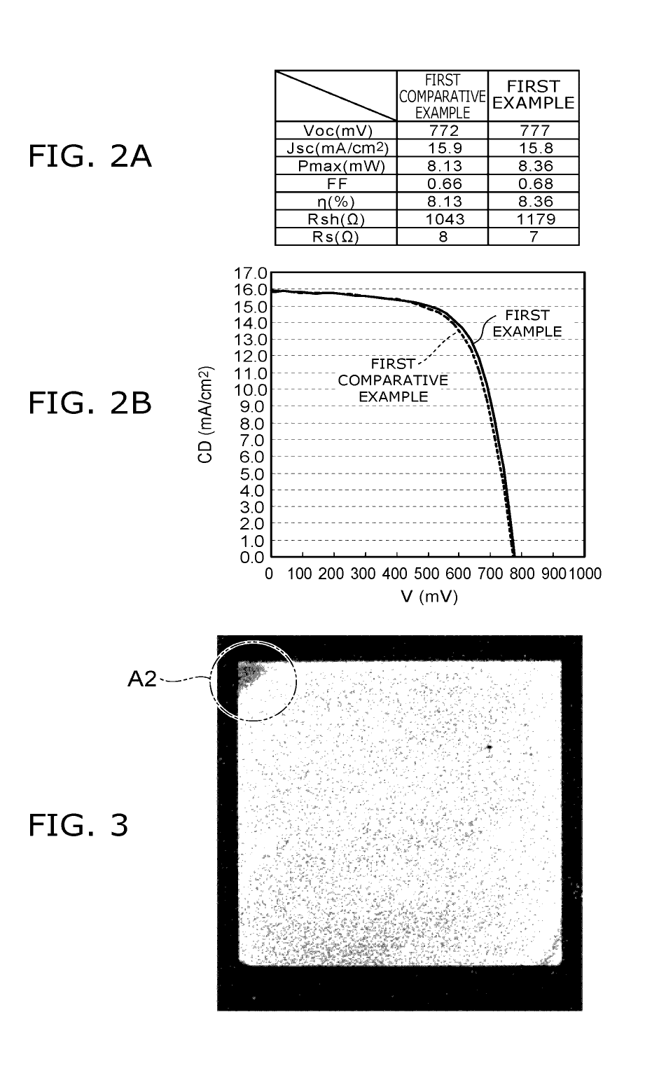

FIG. 2 is a graph describing First Example of the photoelectric conversion element according to the embodiment.

FIG. 3 shows an EMS (Emission Microscopy) image of the photoelectric conversion element according to First Comparative Example.

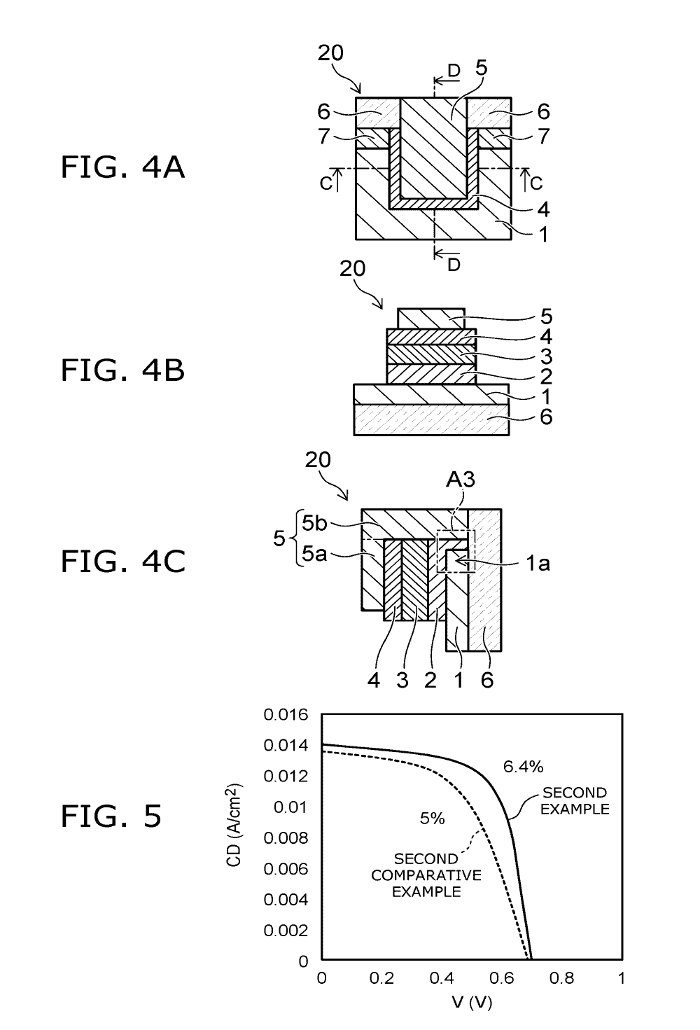

FIG. 4 is a schematic view showing the photoelectric conversion element according to First Comparative Example.

FIG. 2A is a table showing the characteristics of First Example and First Comparative Example. FIG. 2B is a graph illustrating the relationship between voltage and current density. The horizontal axis of the graph in FIG. 2B represents voltage V. The vertical axis of the graph in FIG. 2B represents current density CD. FIG. 4A is a schematic plan view showing the photoelectric conversion element according to the embodiment. FIG. 4B is a schematic cross sectional view taken at plane C-C of FIG. 4A. FIG. 4C is a schematic cross sectional view taken at plane D-D of FIG. 4A.

### First Example

The structure of the photoelectric conversion element 10 according to First Example is as described in conjunction with FIGS. 1A and 1B.

In the photoelectric conversion element 10 according to First Example, a glass plate is used as the substrate 6, and ITO is used as the first electrode 1. PEDOT:PSS is formed as the first buffer layer 2, and LiF is formed as the second buffer layer 4. The first buffer layer 2 functions as a hole transport layer. The second buffer layer 4 functions as an electron transport layer. PTB7 is formed as the p-type organic semiconductor material of the photoelectric conversion layer 3, and a bulk hetero of [70] PCBM is formed as the n-type organic semiconductor material.

After sputtering and forming ITO on the glass substrate, the third buffer layer 7 is formed by vapor depositing LiF at the end portions 1a of the ITO in a thickness of 10 nm. Thereafter, the first buffer layer 2 is formed by spin coating PEDOT:PSS. Here, the photoreceiving surface has a 1 centimeter (cm) square size. Accordingly, the length of the end portion 1a of the ITO (the length of one side of ITO) is 1 cm. The elements forming the first buffer layer 2 are then dried at 120° C. for 10 min. Thereafter, the photoelectric conversion layer 3 is formed by spin coating a solution containing PTB7 and [70] PCBM. The weight ratio of PTB7 and [70] PCBM is 1:2. The solvent is CB containing 3% DIO. Thereafter, the second buffer layer 4 is formed by vapor depositing LiF in a thickness of 0.02 nm, using a vapor deposition device. This is followed by formation of 100-nm AgMg (Mg: 90 wt %) as the second electrode 5. Here, the LiF thickness (as indicated by the thickness meter of the vapor deposition device) is smaller than the diameter, 0.34 nm, of the Li atom. The film is unlikely to be continuous, and the thickness means the average thickness of the film.

An example of the measured characteristics of the photoelectric conversion element 10 according to First Example under the incident light of 100 mW/cm² at an AM (Air Mass) of 1.5 is as shown in FIGS. 2A and 2B.

### First Comparative Example

As shown in FIGS. 4A to 4C, the photoelectric conversion element 20 according to First Comparative Example does not have the third buffer layer 7. In the photoelectric conversion element 20 according to First Comparative Example, the first buffer layer 2 extends to the end portion 1a of the first electrode 1, as shown in FIG. 4C. The other structure is the same as in the photoelectric conversion element 10 according to First Example.

An example of the measured characteristics of the photoelectric conversion element 20 according to First Comparative Example under the incident light of 100 mW/cm² at an AM of 1.5 is as shown in FIGS. 2A and 2B. As shown in FIG. 2A, the conversion efficiency (η (%)) of the photoelectric conversion element 20 according to First Comparative Example is lower than the conversion efficiency of the photoelectric conversion element 10 according to First Example.

It can be seen that there is a current leak at the end portion 1a of the photoelectric conversion element 20 according to First Comparative Example, as indicated by region A2 in FIG. 3. The region A2 in FIG. 3 corresponds to the region A3 (end portion 1a of the first electrode 1) shown in FIG. 4C.

On the other hand, in the photoelectric conversion element 10 according to First Example, the third buffer layer 7 is provided at the end portion 1a of the first electrode 1 (a portion corresponding to region A3 in FIG. 4C). This makes it possible to reduce lowering of shunt resistance, and reduce leakage of current.

### Second Example

FIG. 5 is a graph describing Second Example of the photoelectric conversion element according to the embodiment.

The structure of the photoelectric conversion element 10 according to Second Example is as described in conjunction with FIGS. 1A and 1B.

In the photoelectric conversion element 10 according to First Example, the photoelectric conversion layer 3 has a size of 4.4 millimeters (mm)×23 mm, and the end portion 1a of the first electrode 1 (ITO) is 4.4 mm in length as viewed in the direction of FIG. 1A. Specifically, in the photoelectric conversion element 10 according to First Example, the photoelectric conversion layer 3 and the first electrode 1 are not squares, but are rectangular (excluding a square) in shape. With such shapes of the photoelectric conversion layer 3 and the first electrode 1, the photoelectric conversion element 10 according to Second Example is fabricated in the same configuration as that of the photoelectric conversion element 10 according to First Example.

The photoelectric conversion element according to Second Comparative Example has the same structure as the photoelectric conversion element 20 according to First Comparative Example. Specifically, the structure of the photoelectric conversion element according to Second Comparative Example is as described in conjunction with FIGS. 4A to 4C. The photoelectric conversion layer 3 of Second Comparative Example is rectangular (excluding a square). The first electrode 1 of Second Comparative Example is rectangular (excluding a square).

An example of the measured characteristics of the photoelectric conversion element 10 according to Second Example and the photoelectric conversion element according to Second Comparative Example under the incident light of 100 mW/cm² at an AM of 1.5 is as shown in FIG. 5. As shown in FIG. 5, the conversion efficiency of the photoelectric conversion element 10 according to Second Example is higher than the conversion efficiency of the photoelectric conversion element according to Second Comparative Example.

As demonstrated above, the photoelectric conversion element 10 according to Second Example can reduce lowering of shunt resistance, and reduce a current leak.

### Third Example

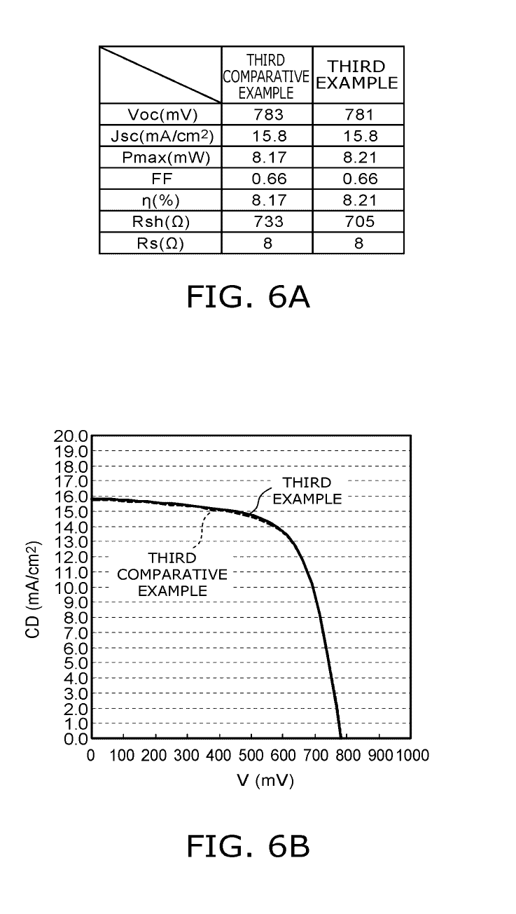

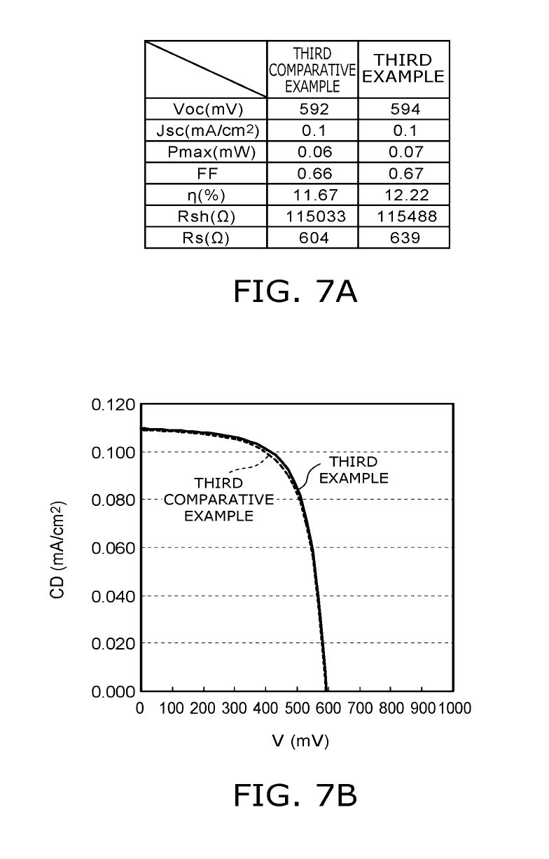

FIGS. 6 and 7 are tables and graphs describing Third Example of the photoelectric conversion element according to the embodiment.

FIGS. 6A and 7A are tables showing the characteristics of Third Example and Third Comparative Example. FIGS. 6B and 7B are graphs illustrating the relationship between voltage and current density. The horizontal axis of the graph in FIGS. 6B and 7B represents voltage V. The vertical axis of the graph in FIGS. 6B and 7B represents current density CD.

The structure of the photoelectric conversion element 10 according to Third Example is as described in conjunction with FIGS. 1A and 1B.

In the photoelectric conversion element 10 according to Third Example, the first buffer layer 2 is ZnO, the second buffer layer 4 and the third buffer layer 7 are V₂O₅, and the second electrode 5 is Ag. In this way, the first buffer layer 2 functions as an electron transport layer. The second buffer layer 4 functions as a hole transport layer. In the photoelectric conversion element 10 according to First Example, the first buffer layer 2 functions as a hole transport layer, and the second buffer layer 4 functions as an electron transport layer.

The photoelectric conversion element according to Third Comparative Example has the same structure as the photoelectric conversion element 20 according to First Comparative Example. Specifically, the structure of the photoelectric conversion element according to Third Comparative Example is as described in conjunction with FIGS. 4A to 4C. In the photoelectric conversion element according to Third Comparative Example, the first buffer layer 2 is ZnO, the second buffer layer 4 is V₂O₅, and the second electrode 5 is Ag.

Electrons are extracted from the first electrode 1, and holes are extracted from the second electrode 5 in the photoelectric conversion element 10 according to Third Example, and in the photoelectric conversion element according to Third Comparative Example. An example of the measured characteristics of the photoelectric conversion element 10 according to Third Example and of the photoelectric conversion element according to Third Comparative Example under the incident light of 100 mW/cm² at an AM of 1.5 is as shown in FIGS. 6A and 6B. An example of the measured characteristics under incident room light (LED) of 1,000 lux is as shown in FIGS. 7A and 7B.

As shown in FIGS. 6A to 7B, the conversion efficiency of the photoelectric conversion element 10 according to Third Example is higher than the conversion efficiency of the photoelectric conversion element according to Third Comparative Example. The photoelectric conversion element 10 according to the embodiment can thus reduce lowering of shunt resistance, and reduce leakage of current, regardless of whether the first buffer layer 2 is a hole transport layer or an electron transport layer. The photoelectric conversion element 10 according to the embodiment also can reduce lowering of shunt resistance, and reduce leakage of current, regardless of whether the second buffer layer 4 is a hole transport layer or an electron transport layer.

The embodiment can provide a photoelectric conversion element that can reduce lowering of shunt resistance.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A photoelectric conversion element comprising:
a first electrode;
a second electrode separated from the first electrode;
a photoelectric conversion layer provided between the first electrode and the second electrode;
a first buffer layer provided between the first electrode and the photoelectric conversion layer;
a second buffer layer provided between the second electrode and the photoelectric conversion layer; and
a third buffer layer provided at an end portion of the first electrode.

2. The element according to claim 1, wherein the second buffer layer includes same material as a material of the third buffer layer.

3. The element according to claim 1, wherein a material of at least one of the first electrode or the second electrode includes a transparent or semi-transparent material having conductivity.

4. The element according to claim 1, wherein a material of at least one of the first electrode or the second electrode includes conductive glass.

5. The element according to claim 1, wherein the material of at least one of the first electrode or the second electrode includes indium tin oxide.

6. The element according to claim 1, wherein at least one of the first electrode or the second electrode has a monolayer structure.

7. The element according to claim 1, wherein at least one of the first electrode or the second electrode has a structure with stacked layers containing materials of different work functions.

8. The element according to claim 1, wherein:
the second electrode includes:
a first portion provided on the second buffer layer, and
a second portion extending from the first portion to the first electrode, and
the third buffer layer includes:
a first buffer portion provided between the first electrode and the first portion, and
a second buffer portion provided between the first electrode and the second portion.

9. The element according to claim 1, wherein a material of the third buffer layer includes a halogen compound or a metal oxide.

10. The element according to claim 9, wherein a material of the second buffer layer includes a halogen compound or a metal oxide.

11. The element according to claim 1, wherein a material of the third buffer layer includes LiF.

12. The element according to claim 11, wherein a material of the second buffer layer includes LiF.

13. The element according to claim 8, wherein the first buffer portion is thicker than the second buffer layer.

14. The element according to claim 1, wherein a material of the first buffer layer includes PEDOT:PSS.

15. The element according to claim 8, wherein the first buffer layer, the photoelectric conversion layer, and the second buffer layer are provided between the first electrode and the first portion.

16. The element according to claim 1, wherein the photoelectric conversion layer includes at least one of an organic semiconductor or a perovskite.

17. The element according to claim 16, wherein the organic semiconductor has a heterojunction.

18. The element according to claim 16, wherein the organic semiconductor has a bulk heterojunction.

19. The element according to claim 16, wherein the organic semiconductor has a p-type organic semiconductor of a polythiophene dielectric.

20. The element according to claim 16, wherein the organic semiconductor has an n-type organic semiconductor of a fullerene dielectric.
